(19) United States
(12) Patent Application Publication
(10) Pub. No.: US 2012/0068275 A1
(43) Pub. Date: Mar. 22, 2012

(54) SEMICONDUCTOR DEVICE AND METHOD FOR FABRICATING THE SAME

(75) Inventor: Tsuyoshi MAKITA, Toyama (JP)

(73) Assignee: PANASONIC CORPORATION, Osaka (JP)

(21) Appl. No.: 13/305,444

(22) Filed: Nov. 28, 2011

Related U.S. Application Data
(63) Continuation of application No. PCT/JP2009/006997, filed on Dec. 18, 2009.

(30) Foreign Application Priority Data
Jun. 24, 2009 (JP) 2009-149431

(51) Int. Cl. H01L 29/772; H01L 21/336; H01L 21/28

(52) U.S. Cl. 257/410; 438/592; 438/287; 257/E21.19; 257/E21.409; 257/E29.242

(57) ABSTRACT

A method for fabricating a semiconductor device includes forming a high-dielectric constant insulating film including a high-dielectric constant film; forming a first conductive film including an oxide film on an upper surface thereof and containing at least one of high melting point metal or a compound thereof; forming a second conductive film containing silicon on the first conductive film with the oxide film being interposed therebetween; forming a mixing layer by performing ion implantation to the first and second conductive films to mix a constituent material of the oxide film and silicon of the second conductive film together; and forming the mixing layer into a conductive layer by performing heat treatment.

### CROSS-REFERENCE TO RELATED APPLICATION

This is a continuation of PCT International Application PCT/JP2009/006997 filed on Dec. 18, 2009, which claims priority to Japanese Patent Application No. 2009-149431 filed on Jun. 24, 2009. The disclosures of these applications including the specifications, the drawings, and the claims are hereby incorporated by reference in their entirety.

### BACKGROUND

A technique disclosed in the present specification relates to a semiconductor device and a method for fabricating the semiconductor device, and particularly relates to a semiconductor device including a gate insulating film containing a high-dielectric constant material and a gate electrode containing high melting point metal and a method for fabricating the semiconductor device.

Recently, as technologies have been rapidly developed for high integration and a high speed operation in a field of semiconductor devices, rapid progress has been also made in miniaturization of transistors. However, since there is a problem that, when a gate insulating film becomes thinner with the miniaturization, gate-leakage current is increased due to tunnel current, study has been conducted to use a high-dielectric constant material such as hafnium oxide (HfO₂), lanthanum oxide (La₂O₃), and zirconium oxide (ZrO₂) as a constituent material of the gate insulating film. In addition, a technique for controlling a work function of a MISFET by using not conventionally-used polysilicon but high melting point metal such as titanium (Ti), tantalum (Ta), and molybdenum (Mo) or a compound thereof as a gate electrode material has been broadly studied.

FIGS. 3A-3E are cross-sectional views illustrating a conventional method for fabricating a CMISFET shown in Y. Inoue et al., Cost Worthy and High Performance LSTP CMIS; Poly-Si/HfSiON nMIS and Poly-Si/TiN/HfSiON pMIS, IEDM Tech Dig, 2006.

In the conventional method, a gate insulating film 31 made of a high-dielectric material and a metal layer 32 made of titanium nitride are first stacked in this order on a semiconductor substrate 30. Subsequently, part of the metal layer 32 provided within an nMIS formation region 40 is selectively removed, and then a polysilicon layer 33 is stacked on the substrate (see FIGS. 3A and 3B). The “nMIS formation region” means a region where an n-channel MISFET is formed, and a “pMIS formation region” which will be described later means a region where a p-channel MISFET is formed.

Next, e.g., lithography is used to form an nMIS gate electrode which includes the polysilicon layer 33 stacked on the semiconductor substrate 30 with the gate insulating film 31 being interposed therebetween in the nMIS formation region 40 and to form a pMIS gate electrode which includes the metal layer 32 and the polysilicon layer 33 stacked on the semiconductor substrate 30 with the gate insulating film 31 being interposed between the metal layer 32 and the semiconductor substrate 30 in the pMIS formation region 42 (see FIG. 3C). Subsequently, a side wall 34 is formed on each of a side surface of the nMIS gate electrode and a side surface of the pMIS gate electrode (see FIG. 3D). Then, n-type source/drain regions are formed in regions of the semiconductor substrate 30 positioned below both sides of the nMIS gate electrode, and p-type source/drain regions are formed in regions of the semiconductor substrate 30 positioned below both sides of the pMIS gate electrode (the source/drain regions are not shown in the figure). Subsequently, a silicide layer 35 is formed on the pMIS gate electrode, the nMIS gate electrode, and each of the source/drain regions (see FIG. 3E).

Since a work function of the gate electrode suitable for an operation is different between the n-channel MISFET (hereinafter briefly referred to as an “nMISFET”) and the p-channel MISFET (hereinafter briefly referred to as a “pMISFET”), the nMIS gate electrode and the pMIS gate electrode have structures different from each other.

### SUMMARY

However, if a gate electrode has a multilayer structure of a metal layer and a polysilicon layer as in the pMISFET of the structure disclosed in the prior art, interface resistance is increased due to a natural oxide film formed between the metal layer and the polysilicon layer, resulting in obstruction of an operation of a transistor.

Typically, when a metal layer made of the foregoing high melting point metal or the compound thereof and a polysilicon layer are stacked to form a gate electrode, a natural oxide film on the metal layer is removed by, e.g., wet etching and then polysilicon is stacked in order to reduce interface resistance between the metal layer and the polysilicon layer. However, it is extremely difficult to prevent formation of the natural oxide film, except that steps after the removal of the natural oxide film and before the stacking of polysilicon are performed in vacuum.

It is considered that, when further progress in miniaturization of transistors is made and power consumption reduction and a high speed operation are accompanied by such progress, a marked influence of a natural oxide film formed between a metal material and polysilicon is provided on a transistor operation. Thus, stabilization of interface resistance and resistance reduction are important.

A semiconductor device of an example embodiment of the present disclosure can realize power consumption reduction and a high speed operation in a state in which the semiconductor device includes a gate insulating film containing a high-dielectric constant material and a gate electrode containing high melting point metal etc.

In order to accomplish the foregoing objective, a semiconductor device fabricating method of a first aspect of one example of the present disclosure includes forming an insulating film including a high-dielectric constant film on a semiconductor substrate; forming a first conductive film including an oxide film formed on an upper surface thereof and containing at least one of high melting point metal or a compound thereof on the insulating film; forming a second conductive film containing silicon on the first conductive film with the oxide film being interposed therebetween; forming a mixing layer by performing ion implantation to the first and second conductive films from above the second conductive film and by mixing a constituent material of the oxide film and silicon of the second conductive film together; and forming the mixing layer into a conductive layer by performing heat treatment.

According to the foregoing method, in the forming the mixing layer and the forming the mixing layer into the conductive layer, the oxide film formed on the first conductive film, such as a natural oxide film can be formed into the conductive layer in a state in which the upper surface of the first conductive film is not exposed. Thus, an increase in resistance at an interface between first and second gate electrodes can be effectively reduced. As a result, power consumption reduction and a high speed operation can be realized even if progress in miniaturization is made. In addition, if a pMISFET and an nMISFET are formed in the same semiconductor substrate, a threshold of each of the MISFETs can be stably controlled.

The method of the first aspect may further include after the forming the mixing layer into the conductive layer, forming a gate electrode including a first gate electrode made of part of the first conductive film, part of the conductive layer, and a second gate electrode made of part of the second conductive film, and a gate insulating film made of part of the insulating film.

In the forming the mixing layer into the conductive layer, the high melting point metal or the compound thereof and silicon may be reacted with each other in the conductive layer, thereby forming a silicide layer.

A semiconductor device fabricating method of a second aspect of the one example of the present disclosure includes forming an insulating film including a high-dielectric constant film on a semiconductor substrate; forming a first conductive film including an oxide film formed on an upper surface thereof and containing at least one of high melting point metal or a compound thereof on the insulating film; forming a second conductive film containing silicon on the first conductive film with the oxide film being interposed therebetween; forming a gate electrode including a first gate electrode made of part of the first conductive film, part of the oxide film, and a second gate electrode made of part of the second conductive film, and a gate insulating film made of part of the insulating film; forming an impurity-doped layer in regions of the semiconductor substrate positioned below both sides of the gate electrode by performing ion implantation of a conductive impurity using the gate electrode as a mask; and, after the forming the impurity-doped layer, forming the impurity-doped layer into an impurity diffusion layer by performing heat treatment to activate the conductive impurity. In the forming the impurity-doped layer, a constituent material of the oxide film and silicon of the second conductive film are mixed together by the ion implantation, thereby simultaneously forming a mixing layer and the impurity-doped layer. In the forming the impurity-doped layer into the impurity diffusion layer, the impurity diffusion layer is formed by the heat treatment and the mixing layer is formed into a conductive layer.

According to the foregoing method, in the forming the impurity-doped layer and the forming the impurity-doped layer into the impurity diffusion layer, the oxide film formed on the first conductive film, such as a natural oxide film can be formed into the conductive layer in a state in which the upper surface of the first conductive film is not exposed. Thus, an increase in resistance at an interface between the first and second gate electrodes can be effectively reduced. As a result, power consumption reduction and a high speed operation can be realized even if progress in miniaturization is made. In addition, the formation of the mixing layer and the ion implantation for forming the impurity-doped layer are simultaneously performed, and the formation of the conductive layer and the heat treatment for forming the impurity diffusion layer are simultaneously performed. Thus, the advantages similar to those of the fabricating method of the first aspect can be realized with the number of steps less than those of the fabricating method of the first aspect.

In the forming the impurity-doped layer, when a film thickness of the second gate electrode is represented by h and a depth of the impurity-doped layer is represented by d, the ion implantation may be performed under conditions where h≦d is satisfied.

In the forming the impurity-doped layer into the impurity diffusion layer, the high melting point metal or the compound thereof and silicon may be reacted with each other in the conductive layer, thereby forming a silicide layer.

The high-dielectric constant film may contain at least one of Hf, Zr, La, Al, Lu, or Gd.

The high melting point metal may contain at least one of Ti, Ta, Nb, W, Mo, or V.

The second conductive film may be made of polysilicon or amorphous silicon.

A semiconductor device in one example of the present disclosure includes a gate insulating film formed on a semiconductor substrate and including a high-dielectric constant film; and a gate electrode including a first gate electrode formed on the gate insulating film and containing at least one of high melting point metal or a compound thereof, a second gate electrode formed on the first gate electrode and containing silicon, and a conductive layer formed at an interface between the first and second gate electrodes. An oxide of the high melting point metal and silicon are mixed together in the conductive layer.

According to the foregoing configuration, since the conductive layer is formed at the interface between the first and second gate electrodes, an increase in resistance at the interface between the first and second gate electrodes is reduced. Thus, a work function of the gate electrode can be controlled to a suitable value while realizing power consumption reduction and a high speed operation.

The semiconductor device may further include an impurity diffusion layer formed in regions of the semiconductor substrate positioned below both sides of the gate electrode and containing a conductive impurity. The second gate electrode contains the conductive impurity.

When a film thickness of the second gate electrode is represented by h and a depth of the impurity diffusion layer is represented by d, h≦d may be satisfied.

The oxide of the high melting point metal and silicon may form an amorphous layer in the conductive layer.

The conductive layer may include a silicide layer made of the high melting point metal.

The high-dielectric constant film may contain at least one of Hf, Zr, La, Al, Lu, or Gd.

The high melting point metal may contain at least one of Ti, Ta, Nb, W, Mo, or V.

The second gate electrode may be made of polysilicon or amorphous silicon.

According to the semiconductor device of the one example of the present disclosure and the method for fabricating the semiconductor device, insulating properties of the oxide film interposed between the first conductive film (first gate electrode) containing the high melting point metal or the compound thereof and the second conductive film (second gate electrode) formed on the first conductive film and containing silicon can be reduced. Thus, the increase in resistance at the interface between the first and second gate electrodes can be effectively reduced, thereby realizing the power consumption reduction and the high speed operation of the semiconductor device.

### BRIEF DESCRIPTION OF THE DRAWINGS

FIGS. 1A-1F are cross-sectional views illustrating steps in one example of a semiconductor device fabricating method of a first embodiment of the present disclosure.

FIGS. 2A-2D are cross-sectional views illustrating steps in one example of a semiconductor device fabricating method of a second embodiment of the present disclosure.

FIGS. 3A-3E are cross-sectional views illustrating a conventional method for fabricating a CMISFET.

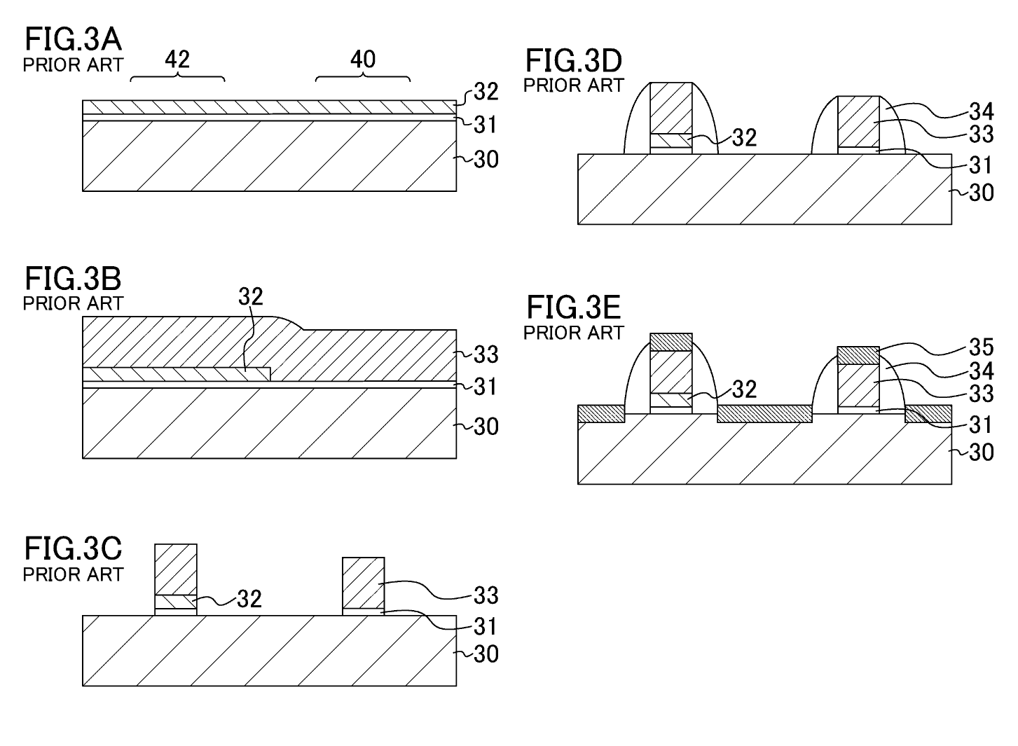

### DETAILED DESCRIPTION

### First Embodiment

A semiconductor device of a first embodiment of the present disclosure and a method for fabricating the semiconductor device will be described below with reference to the drawings. A pMISFET will be described below as an example. Note that, in the present specification, a “high-dielectric substance” means a material having a dielectric constant greater than at least that of silicon oxide. In addition, “high melting point metal” means metal having a melting point of equal to or higher than 1500° C.

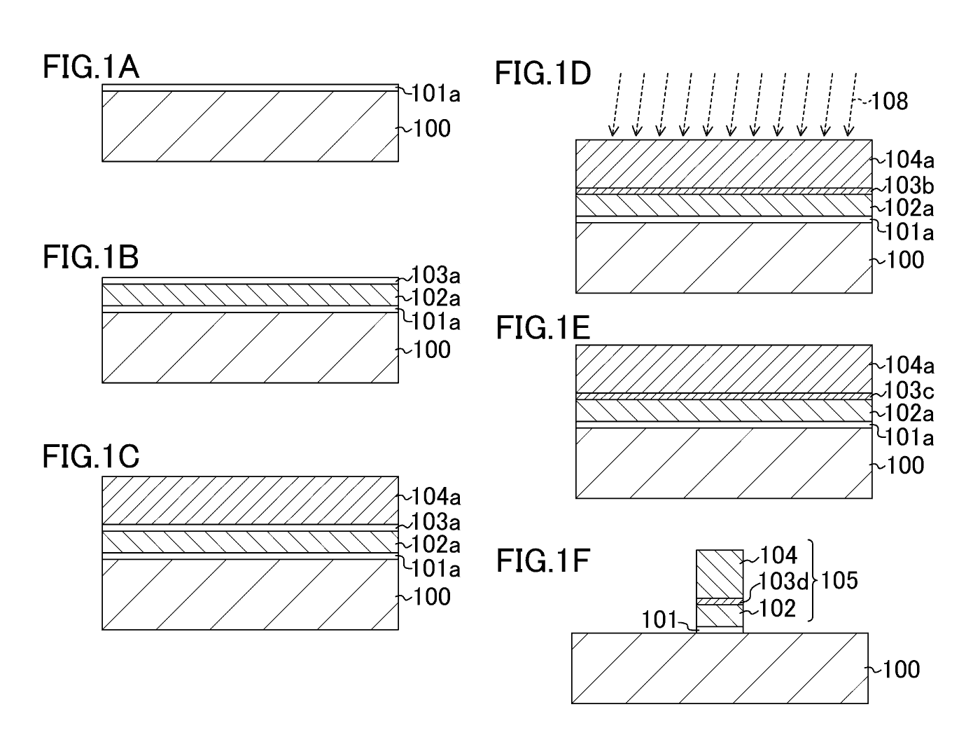

FIGS. 1A-1F are cross-sectional views illustrating steps in one example of the semiconductor device fabricating method of the first embodiment.

First, as illustrated in FIG. 1A, a high-dielectric constant insulating film 101a is formed on a semiconductor substrate 100 made of, e.g., silicon. Examples of the high-dielectric constant insulating film 101a include a hafnium oxide film formed by, e.g., atomic layer deposition (ALD) and having a thickness of about 2 nm, and a multilayer film of a silicon oxide film formed by thermal oxidation and a high-dielectric film such as a hafnium oxide film.

Subsequently, as illustrated in FIG. 1B, a first conductive film 102a made of, e.g., high melting point metal or a compound of high melting point metal having conductivity is formed on the high-dielectric constant insulating film 101a. The first conductive film 102a is provided for the purpose of controlling a work function of a gate electrode which will be formed later, and may be a film containing at least one of the high melting point metal or the compound thereof. The first conductive film 102a may be a high melting point metal film, a high melting point metal compound film, or a multilayer film thereof. The first conductive film 102a may be, e.g., a TaN single layer film formed by physical vapor deposition (PVD) and having a thickness of about 20 nm, or a multilayer film of a TaN film and a Ta film with a total thickness of about 20 nm. When the first conductive film 102a is formed, a natural oxide film 103a having a thickness of equal to or less than 1 nm is formed on the first conductive film 102a.

Next, as illustrated in FIG. 1C, a second conductive film 104a made of a silicon material is formed on the first conductive film 102a with the natural oxide film 103a being interposed therebetween. As the second conductive film 104a, e.g., a polysilicon film formed by chemical vapor deposition (CVD) and having a thickness of 100 nm is used. Note that, other than silicon, the second conductive film 104a may be made of semiconductor containing silicon, such as SiGe.

Next, as illustrated in FIG. 1D, ion implantation 108 of an impurity is performed for a substrate (at least the first conductive film 102a and the second conductive film 104a) from above the second conductive film 104a, thereby forming the natural oxide film 103a into a mixing layer 103b. The mixing layer 103b is formed by mixing a constituent material (oxygen) of the natural oxide film 103a and a constituent material of the second conductive film 104a together by using ion energy. At this step, e.g., phosphorus ions are implanted under the following conditions: accelerating voltage of 20 keV and an implantation amount of 5×10¹⁵ ion/cm². As a result, the natural oxide film 103a is formed into the mixing layer 103b. In this state, as an implantation ion species, phosphorus, arsenic, or boron (B) may be used for the purpose of controlling resistance of polysilicon (the second conductive film 104a), or argon (Ar) or nitrogen (N) may be used. The ion implantation amount required for the formation of the mixing layer 103b is 1×10¹⁵ ion/cm², but the ion species is not limited. Since an ion implantation amount required for source/drain regions is about 10¹⁵ ion/cm², such an ion implantation amount can be also applied for the mixing.

Next, as illustrated in FIG. 1E, heat treatment is performed at 600° C. by, e.g., an electric furnace, a lamp heating technique, or a laser heating technique, and therefore the mixing layer 103b formed from the natural oxide film 103a and the second conductive film 104a is formed into an interface conductive layer 103c. The thickness of the interface conductive layer 103c changes depending on the ion accelerating voltage and the heat treatment temperature, and is, e.g., about 2-5 nm. In this state, the high melting point metal contained in the first conductive film 102a and the material (e.g., polysilicon) of the second conductive film 104a are reacted with each other in the interface conductive layer 103c, thereby changing into an amorphous state.

Note that, if a first gate electrode has a multilayer structure of a TaN film and a Ta film, the interface conductive layer 103c is made of Ta silicide. If high melting point metal other than the Ta film is used, the interface conductive layer 103c can be also made of metal silicide.

Next, as illustrated in FIG. 1F, anisotropic dry etching using, e.g., a resist (not shown in the figure) formed by photolithography is performed, thereby forming a gate electrode 105 on the high-dielectric constant insulating film 101a. The gate electrode 105 includes, in this order from bottom, a first gate electrode 102 which is part of the first conductive film 102a, an interface conductive layer 103d which is part of the interface conductive layer 103c, and a second gate electrode 104 which is part of the second conductive film 104a. Subsequently, the high-dielectric constant insulating film 101a is removed by wet etching in a state in which part of the high-dielectric constant insulating film 101a sandwiched between the semiconductor substrate 100 and the gate electrode 105 remains, thereby forming a gate insulating film 101.

As illustrated in FIG. 1F, the semiconductor device of the present embodiment, which is fabricated by the foregoing method includes the semiconductor substrate 100, the gate insulating film 101 formed on the semiconductor substrate and made of the high dielectric body etc., and the gate electrode 105 formed on the gate insulating film 101.

The gate electrode 105 includes the first gate electrode 102 formed on the gate insulating film 101 and containing the metal or the conductive metal compound, the interface conductive layer 103d formed on the first gate electrode 102, and the second gate electrode 104 formed on the interface conductive layer 103d and made of polysilicon etc. Although not shown in the figure, an impurity diffusion region containing a p-type impurity such as phosphorous is formed in a region of the semiconductor substrate 100, which is positioned below each of both sides of the gate electrode 105. The first gate electrode 102 contains the high melting point metal, and is e.g., a multilayer film made of a Ta film and a TaN film.

The interface conductive layer 103d contains, in the amorphous state, the high melting point metal contained in the first gate electrode 102 and the silicon contained in the second gate electrode 104, and shows conductivity.

In the semiconductor device fabricating method of the present embodiment, the ion implantation 108 is performed from above the second conductive film 104a by energy which allows ions to reach at least the natural oxide film 103a at the step illustrated in FIG. 1D. At this step, the natural oxide film 103a and part of the second conductive film 104a contacting the mixing layer 103b are mixed together by the energy of the ions of the implanted substance, and the heat treatment is performed at the subsequent step illustrated in FIG. 1E. In such a manner, the natural oxide film 103a can be formed into the interface conductive layer 103c. The interface conductive layer 103c is formed into the interface conductive layer 103d sandwiched between the first gate electrode 102 and the second gate electrode 104.

According to the method of the present embodiment, since an insulating film is not formed between the first gate electrode 102 and the second gate electrode 104, an increase in interface resistance between the first gate electrode 102 and the second gate electrode 104 can be reduced. In particular, the natural oxide film 103a is modified in a state in which an upper surface of the first gate electrode 102 (first conductive film 102a) is not exposed, and therefore the natural oxide film 103a is not reformed as compared to a method for removing a natural oxide film 103a before a second conductive film 104a is formed. Thus, reduction in interface resistance in the gate electrode 105 can be stably ensured, and, as a result, power consumption reduction and resistance reduction of a MISFET can be realized even if progress in miniaturization is made. In addition, if an nMISFET and a pMISFET are formed in the same substrate, the work function can be easily controlled, thereby easily controlling a threshold of each of the MISFETs.

Note that, after the first conductive film 102a having, e.g., the multilayer structure of the TaN film and the Ta film is formed at the step illustrated in FIG. 1B, the heat treatment is performed at 600° C. at the step illustrated in FIG. 1E, and, as a result, the interface conductive layer 103c formed at an interface between the first conductive film 102a which will be formed into the first gate electrode 102 and the second conductive film 104a which will be formed into the second gate electrode 104 can be made of Ta silicide. In such a case, the interface resistance in the gate electrode 105 can be further reduced as compared to a case where the interface conductive layer 103c includes an amorphous layer.

The method for fabricating only the pMISFET has been described as the example in the present embodiment. However, if the nMISFET and the pMISFET are formed on the semiconductor substrate 100, part of the first conductive film 102a formed on a pMIS formation region of the semiconductor substrate 100 may be removed, e.g., after the step illustrated in FIG. 1B. Subsequently, an n-type impurity may be implanted in a state in which a mask is formed so as to cover the pMIS formation region at the step illustrated in FIG. 1D, and then an nMIS gate electrode including the second conductive film 104a may be formed at the step illustrated in FIG. 1F.

### Second Embodiment

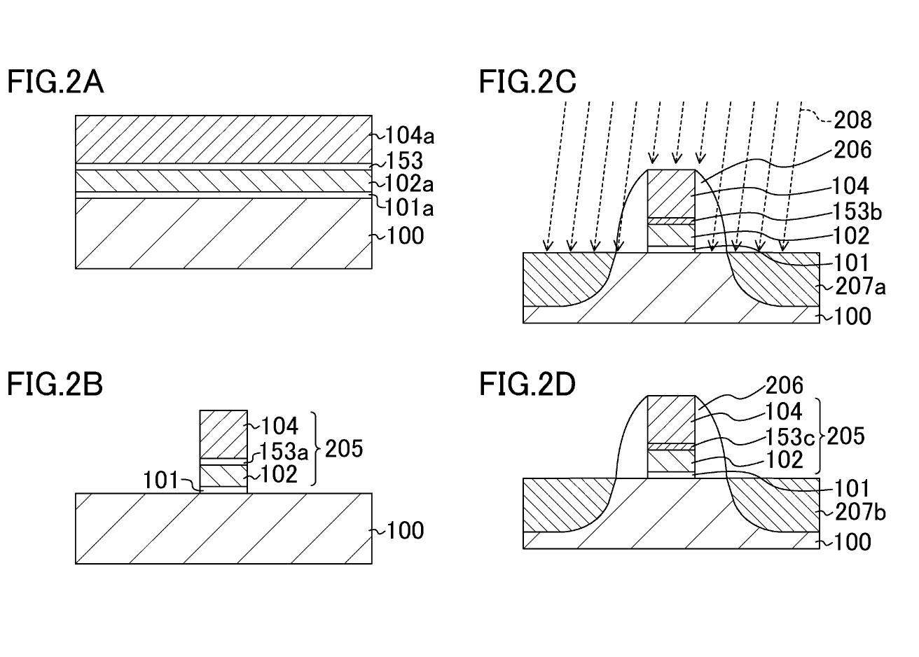

A semiconductor device of a second embodiment of the present disclosure and a method for fabricating the semiconductor device will be described below with reference to FIG. 2. An nMISFET will be described below as an example.

FIGS. 2A-2D are cross-sectional views illustrating steps in one example of the semiconductor device fabricating method of the second embodiment.

First, as illustrated in FIG. 2A, a high-dielectric constant insulating film 101a, a first conductive film 102a, and a second conductive film 104a are formed in this order on a semiconductor substrate 100 in the similar manner to the steps of the first embodiment as illustrated in FIGS. 1A-1C.

Specifically, e.g., a hafnium oxide film formed by ALD and having a thickness of about 2 nm, or a multilayer film of a silicon oxide film and a hafnium oxide film, which is formed by thermal oxidation is formed on the semiconductor substrate 100 as the high-dielectric constant insulating film 101a. Subsequently, the second conductive film 104a containing high melting point metal or a compound thereof is formed on the high-dielectric constant insulating film 101a. The first conductive film 102a is provided for the purpose of controlling a work function of a gate electrode which will be formed later. Examples of the second conductive film 104a include a TaN film formed by, e.g., PVD and having an overall thickness of about 20 nm, and a multilayer film of a TaN film and a Ta film, which has a total thickness of about 20 nm. Note that, at this step, when the first conductive film 102a is formed, a natural oxide film 153 having a thickness of equal to or less than about 1 nm is formed on the first conductive film 102a.

Next, the second conductive film 104a made of a silicon material is formed on the first conductive film 102a, on an upper surface of which the natural oxide film 153 is formed. Examples of the second conductive film 104a include a polysilicon film formed by CVD and having a thickness of 100 nm.

Next, as illustrated in FIG. 2B, anisotropic dry etching is performed by using a mask (not shown in the figure) formed by photolithography and patterning, and the first conductive film 102a, the natural oxide film 153, and the second conductive film 104a are removed in a state in which each of the first conductive film 102a, the natural oxide film 153, and the second conductive film 104a partially remains. In such a manner, a gate electrode 205 is formed, which includes a first gate electrode 102 made of the part of the first conductive film 102a, a natural oxide film 153a made of the part of the natural oxide film 153, and a second gate electrode 104 made of the part of the second conductive film 104a.

Next, part of the high-dielectric constant insulating film 101a is removed by wet etching using the foregoing mask, thereby forming a gate insulating film 101 between the semiconductor substrate 100 and the first gate electrode 102. Subsequently, the mask is removed.

Next, as illustrated in FIG. 2C, a lightly doped drain (LDD) side wall 206 is formed on a side surface of the gate electrode 205, conductive impurity ions are implanted to the gate electrode 205 and the semiconductor substrate 100. As one example, ion implantation 208 of arsenic ions is performed under predetermined conditions (accelerating voltage of 20 keV and an implantation amount of 2×10¹⁵ ion/cm²), and then impurity-doped layers 207a which will be formed into source/drain regions or extension regions is formed in regions positioned below both sides of the gate electrode 205. The ion implantation 208 allows both of formation of the impurity-doped layer 207a and formation of a mixing layer 153b from the natural oxide film 153a at an interface between the first gate electrode 102 and the second gate electrode 104. In the mixing layer 153b, a constituent material of the natural oxide film 153a and polysilicon of the second gate electrode 104 are mixed together. Note that, in such a state, ion implantation conditions are preferred, under which a relationship of h≦d is satisfied between a material film thickness h of the second gate electrode 104 and a depth d of the impurity-doped layers 207a.

Next, as illustrated in FIG. 2D, heat treatment is performed for the semiconductor substrate 100 at 600° C. by, e.g., an electric furnace, a lamp heating technique, or a laser heating technique, and therefore an interface conductive layer 153c is formed by reacting the constituent material of the natural oxide film 153a and polysilicon mixed together in the mixing layer 153b with each other. The heat treatment allows activation of a conductive impurity in the impurity-doped layers 207a, thereby forming impurity diffusion layers 207b.

Unlike the first embodiment, in the semiconductor device fabricating method of the present embodiment, ion implantation only for mixing is not performed, and the mixing layer 153b is formed by using energy of the ion implantation for forming the impurity diffusion layer 207b which will be the source/drain region or the extension region after the gate electrode 205 is formed. The heat treatment for reacting the high melting point metal, polysilicon, etc. of the mixing layer 153b with each other is also used as the heat treatment for forming the impurity diffusion layers 207b.

According to the method of the present embodiment, an insulating natural oxide film formed at the interface between the first gate electrode 102 and the second gate electrode 104 in the gate electrode 205 can be modified into the interface conductive layer 153c without being exposed to oxygen, and therefore an increase in resistance at the interface between the first gate electrode 102 and the second gate electrode 104 can be effectively reduced as compared to a conventional method.

In particular, in a case where the first gate electrode 102 contains high melting point metal forming silicide by reacting with silicon, such as a case where the first gate electrode 102 is a multilayer film of a TaN film and a Ta film, the interface conductive layer 153c is made of metal silicide. Thus, the increase in resistance at the interface between the first gate electrode 102 and the second gate electrode 104 can be more effectively reduced. As a result, the work function of the gate electrode can be easily controlled.

According to the fabricating method of the present embodiment, the mixing of the natural oxide film 153a and the subsequent heat treatment are also used as a step for forming the impurity diffusion layers 207b, and therefore resistance in the gate electrode 205 can be reduced with the number of steps less than those of the first embodiment.

The film containing Hf has been described as the example of the high-dielectric constant insulating film 101a in the semiconductor device fabricating methods of the first and second embodiments, but the present disclosure is not limited to such a film. The gate insulating film 101 (and the high-dielectric constant insulating film 101a) may be a film containing one or more materials selected from a group of, e.g., Hf, Zr, lanthanum (La), Al, lutetium (Lu), and gadolinium (Gd).

In the fabricating methods of the first and second embodiments of the present disclosure, the example has been described, in which Ta is used as the high melting point metal and TaN is used as the compound of the high melting point metal, but the present disclosure is not limited to such an example. The first gate electrode 102 (and the first conductive film 102a) may be a film containing one or more materials selected from a group of, e.g., Ti, Ta, niobium (Nb), tungsten (W), Mo, and vanadium (V). Alternatively, the first gate electrode 102 (and the first conductive film 102a) may be a film made of a conductive compound of the foregoing high melting point metals.

In the fabricating methods of the first and second embodiments, polysilicon has been described as the example of the constituent material of the second gate electrode 104, but the present disclosure is not limited to such a material. Amorphous silicon may be used as the constituent material of the second gate electrode 104.

As described above, configurations of the embodiments of the present disclosure are useful for the semiconductor device including the gate insulating film containing the high-dielectric constant material and the gate electrode containing the high melting point metal and the method for fabricating the semiconductor device.

What is claimed is:

1. A method for fabricating a semiconductor device, comprising:
forming an insulating film including a high-dielectric constant film on a semiconductor substrate;
forming a first conductive film including an oxide film formed on an upper surface thereof and containing at least one of high melting point metal or a compound thereof on the insulating film;
forming a second conductive film containing silicon on the first conductive film with the oxide film being interposed therebetween;
forming a mixing layer by performing ion implantation to the first and second conductive films from above the second conductive film and by mixing a constituent material of the oxide film and silicon of the second conductive film together; and
forming the mixing layer into a conductive layer by performing heat treatment.

2. The method of claim 1, further comprising:
after the forming the mixing layer into the conductive layer, forming a gate electrode including a first gate electrode made of part of the first conductive film, part of the conductive layer, and a second gate electrode made of part of the second conductive film, and a gate insulating film made of part of the insulating film.

3. The method of claim 1, wherein
in the forming the mixing layer into the conductive layer, the high melting point metal or the compound thereof and silicon are reacted with each other in the conductive layer, thereby forming a silicide layer.

4. A method for fabricating a semiconductor device, comprising:
forming an insulating film including a high-dielectric constant film on a semiconductor substrate;
forming a first conductive film including an oxide film formed on an upper surface thereof and containing at least one of high melting point metal or a compound thereof on the insulating film;
forming a second conductive film containing silicon on the first conductive film with the oxide film being interposed therebetween;
forming a gate electrode including a first gate electrode made of part of the first conductive film, part of the oxide film, and a second gate electrode made of part of the second conductive film, and a gate insulating film made of part of the insulating film;
forming an impurity-doped layer in regions of the semiconductor substrate positioned below both sides of the gate electrode by performing ion implantation of a conductive impurity using the gate electrode as a mask; and
after the forming the impurity-doped layer, forming the impurity-doped layer into an impurity diffusion layer by performing heat treatment to activate the conductive impurity,
wherein, in the forming the impurity-doped layer, a constituent material of the oxide film and silicon of the second conductive film are mixed together by the ion implantation, thereby simultaneously forming a mixing layer and the impurity-doped layer, and
in the forming the impurity-doped layer into the impurity diffusion layer, the impurity diffusion layer is formed by the heat treatment and the mixing layer is formed into a conductive layer.

5. The method of claim 4, wherein
in the forming the impurity-doped layer, when a film thickness of the second gate electrode is represented by h and a depth of the impurity-doped layer is represented by d, the ion implantation is performed under conditions where h≦d is satisfied.

6. The method of claim 4, wherein
in the forming the impurity-doped layer into the impurity diffusion layer, the high melting point metal or the compound thereof and silicon are reacted with each other in the conductive layer, thereby forming a silicide layer.

7. The method of claim 1, wherein
the high-dielectric constant film contains at least one of Hf, Zr, La, Al, Lu, or Gd.

8. The method of claim 1, wherein
the high melting point metal contains at least one of Ti, Ta, Nb, W, Mo, or V.

9. The method of claim 1, wherein
the second conductive film is made of polysilicon or amorphous silicon.

10. A semiconductor device, comprising:
a gate insulating film formed on a semiconductor substrate and including a high-dielectric constant film; and
a gate electrode including a first gate electrode formed on the gate insulating film and containing at least one of high melting point metal or a compound thereof, a second gate electrode formed on the first gate electrode and containing silicon, and a conductive layer formed at an interface between the first and second gate electrodes,
wherein an oxide of the high melting point metal and silicon are mixed together in the conductive layer.

11. The semiconductor device of claim 10, further comprising:
an impurity diffusion layer formed in regions of the semiconductor substrate positioned below both sides of the gate electrode and containing a conductive impurity,
wherein the second gate electrode contains the conductive impurity.

12. The semiconductor device of claim 11, wherein
when a film thickness of the second gate electrode is represented by h and a depth of the impurity diffusion layer is represented by d, h≦d is satisfied.

13. The semiconductor device of claim 10, wherein
the oxide of the high melting point metal and silicon form an amorphous layer in the conductive layer.

14. The semiconductor device of claim 10, wherein
the conductive layer includes a silicide layer made of the high melting point metal.

15. The semiconductor device of claim 10, wherein
the high-dielectric constant film contains at least one of Hf, Zr, La, Al, Lu, or Gd.

16. The semiconductor device of claim 10, wherein
the high melting point metal contains at least one of Ti, Ta, Nb, W, Mo, or V.

17. The semiconductor device of claim 10, wherein
the second gate electrode is made of polysilicon or amorphous silicon.
